(19) United States
(12) Patent Application Publication
(10) Pub. No.: US 2026/0218368 A1
(43) Pub. Date: Jul. 30, 2026

(54) DEPOSITION DEVICE FOR PREVENTING VIBRATION

(71) Applicant: SUNIC SYSTEM. LTD., Suwon-si (KR)

(72) Inventors: Yeong Beom KIM, Suwon-si (KR); Sang Gyu JEONG, Suwon-si (KR); In Ho HWANG, Suwon-si (KR)

(73) Assignee: SUNIC SYSTEM. LTD., Suwon-si (KR)

(21) Appl. No.: 19/143,367

(22) PCT Filed: Dec. 22, 2023
(86) PCT No.: PCT/KR2023/021447

§ 371 Date: Jun. 25, 2025

(30) Foreign Application Priority Data
Dec. 26, 2022 (KR) 10-2022-0183905
Jan. 19, 2023 (KR) 10-2023-0008071

(51) Int. Cl. C23C 14/24; C23C 14/04; C23C 14/54; H10K 71/16

(52) U.S. Cl. CPC C23C 14/24; C23C 14/042; C23C 14/54; H10K 71/164

(57) ABSTRACT

A deposition device may include: a deposition chamber configured to provide a deposition space; a first plate configured to be separable from an upper side of the deposition chamber; a second plate disposed above the first plate; a hexapod connected to the second plate and extending to the deposition space while passing through the first plate; an electrostatic chuck disposed below the hexapod and configured to fix a substrate onto which deposition particles are to be deposited; a first support part extending from the second plate to the deposition space and configured to support a mask configured to face the substrate; and a vibration prevention part disposed between the first plate and the second plate and configured to prevent vibration of the first plate from being transmitted to the second plate.

### CROSS REFERENCE TO THE RELATED APPLICATIONS

This application is the national phase entry of International Application No. PCT/KR2023/021447, filed on Dec. 22, 2023, which is based upon and claims priority to Korean Patent Applications No. 10-2022-0183905, filed on Dec. 26, 2022, and No. 10-2023-0008071, filed on Jan. 19, 2023, the entire contents of which are incorporated herein by reference.

### TECHNICAL FIELD

The present disclosure relates to a deposition technology, and more particularly, to a deposition device that improves deposition quality by preventing vibration during a deposition process.

### BACKGROUND

Recently, there has been a significantly increasing demand for organic light-emitting diodes (OLEDs) in display markets. In particular, there is a growing demand for organic light-emitting diode (OLED) displays with high resolution and large sizes in the markets for television displays and smartphone displays.

Among processes of manufacturing the organic light-emitting diodes (OLEDs) for implementing high resolution of the displays, a key process is a deposition process for manufacturing RGB pixels. During the deposition process, a deposition source positioned at a lower end of a chamber heats an organic material, and the heated organic material is sublimated. The sublimated organic material passes through a mask and is deposited on a substrate to form a thin-film transistor (TFT).

Further, the thin-film transistor having a small size needs to be deposited to implement a high-resolution display.

However, in case that the substrate is finely curved, there is a problem in that deposition quality deteriorates during the deposition process for manufacturing the thin-film transistor having a small size.

In addition, there is a problem in that deposition quality deteriorates in case that vibration, which is caused by a mechanical motion in the chamber, is transmitted to the chamber or vibration, which is generated from the outside of the chamber, is transmitted to the chamber.

Meanwhile, the deposition source moves in the chamber and sprays the sublimated organic material uniformly onto the substrate or sprays the sublimated organic material to an appropriate position.

However, the movement of the deposition source transmits vibration to the chamber, which causes a problem of a deterioration in uniformity of the deposition onto the substrate.

Further, the vibration caused by the movement of the deposition source affects various types of sensors provided in the chamber, which makes it difficult to precisely control the deposition process.

### SUMMARY

### Technical Problem

The present disclosure has been made in an effort to solve the above-mentioned problem, and an object of the present disclosure is to provide a deposition device that prevents a deterioration in deposition quality caused by vibration.

Another object of the present disclosure is to provide a deposition device that precisely controls deposition uniformity by minimizing an influence of vibration caused by a movement of a deposition source.

Technical problems to be solved by the present disclosure are not limited to the above-mentioned technical problems, and other technical problems, which are not mentioned above, may be clearly understood from the following descriptions by those skilled in the art to which the present disclosure pertains.

### Technical Solution

One aspect of the present disclosure provides a deposition device including: a deposition chamber configured to provide a deposition space; a first plate configured to be separable from an upper side of the deposition chamber; a second plate disposed above the first plate; a hexapod connected to the second plate and extending to the deposition space while passing through the first plate; an electrostatic chuck disposed below the hexapod and configured to fix a substrate onto which deposition particles are to be deposited; a first support part extending from the second plate to the deposition space and configured to support a mask configured to face the substrate; and a vibration prevention part disposed between the first plate and the second plate and configured to prevent vibration of the first plate from being transmitted to the second plate.

In this case, the vibration prevention part may be provided as a plurality of vibration prevention parts, and the plurality of vibration prevention parts may be disposed to be spaced apart from one another at equal intervals.

In this case, the vibration prevention part may include: a body part configured to be expanded by air introduced into the body part; a pump configured to inject air into the body part; and a controller configured to control the pump.

In this case, the vibration prevention part may include: a body part disposed above the first plate; a vibration sensor part provided on the body part and configured to detect vibration; a vibration canceling part configured to generate an inverted sound range to cancel the vibration; and a controller configured to control the vibration canceling part in response to an electrical signal transmitted from the vibration sensor part.

The vibration canceling part may include a linear motor configured to generate an inverted sound range.

In this case, the deposition device may further include: a third plate disposed above the second plate; a second support part extending from any one of the second plate or the third plate to the deposition space and configured to move in an upward/downward direction of the deposition chamber; and a magnetic part connected to the second support part and disposed above the electrostatic chuck.

In this case, the deposition device may further include: a mask support part connected to the first support part and configured to support the mask, in which the mask support part is made of a metallic material, and in which the magnetic part pulls the mask support part when the magnetic part moves to be close to the electrostatic chuck.

In this case, the mask may be made of a metallic material, and the magnetic part may pull the mask when the magnetic part moves to be close to the electrostatic chuck.

In addition, another aspect of the present disclosure provides a deposition device including: a deposition chamber configured to maintain a vacuum state and configured to accommodate a substrate onto which deposition particles are to be deposited; a deposition source accommodated in the deposition chamber and configured to spray the deposition particles; a guide rail configured to guide a movement of the deposition source; a support part configured to support the guide rail and penetrate a through-hole formed in a lower portion of the deposition chamber; and an inflow prevention part configured to prevent air present outside the deposition chamber from being introduced through the through-hole.

The inflow prevention part may have a corrugated shape.

In this case, the inflow prevention part may be formed to surround a part of the support part disposed outside the deposition chamber.

In this case, the deposition chamber may include: an upper portion disposed above the lower portion; and a plurality of lateral portions disposed between the lower portion and the upper portion, and the guide rail may be disposed to be spaced apart from the plurality of lateral portions at predetermined intervals.

In addition, the guide rail and the support part may not be in contact with the deposition chamber.

### Advantageous Effects

With the above-mentioned configuration, the deposition device according to the embodiment of the present disclosure prevents vibration from being transmitted to the hexapod, thereby preventing a deterioration in deposition quality caused by vibration.

In addition, the substrate is prevented from being curved, and the flatness of the substrate is improved, which may implement a high-resolution display.

In the deposition device according to the embodiment of the present disclosure, the support part, which supports the deposition source, penetrates the lower portion of the deposition chamber without being in contact with the deposition chamber, and vibration of the deposition source is prevented from being transmitted to the deposition chamber, such that the deposition uniformity may be precisely controlled.

In addition, the inflow prevention part may stably maintain the vacuum state of the deposition chamber even though a part of the support part is disposed outside the deposition chamber.

### BRIEF DESCRIPTION OF THE DRAWINGS

FIG. 1 is a view schematically illustrating a deposition device according to an embodiment of the present disclosure.

FIG. 2 is a view focusing on an interior of the deposition device according to the embodiment of the present disclosure.

FIG. 3 is a perspective view illustrating a state in which vibration prevention parts of the deposition device according to the embodiment of the present disclosure are disposed on a first plate.

FIG. 4 is a block diagram illustrating the vibration prevention part of the deposition device according to the embodiment of the present disclosure.

FIG. 5 is a block diagram illustrating a vibration prevention part of a deposition device according to another embodiment of the present disclosure.

FIG. 6 is a view schematically illustrating a deposition device according to still another embodiment of the present disclosure.

FIG. 7 is a perspective view schematically illustrating an interior of the deposition device according to still another embodiment of the present disclosure.

FIG. 8 is a view illustrating a state in which a guide rail is spaced apart from a deposition chamber in the deposition device according to still another embodiment of the present disclosure.

100: Deposition device
110: Deposition chamber
210: First plate
220: Second plate
221: First support part
240: Hexapod
250: Electrostatic chuck
280: Vibration prevention part

### DETAILED DESCRIPTION OF THE EMBODIMENTS

Hereinafter, an embodiment of the present disclosure will be described in detail with reference to the accompanying drawings so that those skilled in the technical field to which the present disclosure pertains may easily carry out the embodiment. The present disclosure may be implemented in various different ways, and is not limited to the embodiments described herein. In the drawings, a part irrelevant to the description will be omitted to clearly describe the present disclosure, and the same or similar constituent elements will be designated by the same reference numerals throughout the specification.

Terms or words used in the specification and the claims should not be interpreted as being limited to a general or dictionary meaning and should be interpreted as a meaning and a concept which conform to the technical spirit of the present disclosure based on a principle that an inventor can appropriately define a concept of a term in order to describe his/her own invention by the best method.

Therefore, the embodiments disclosed in the present specification and the configurations illustrated in the drawings are the exemplary embodiments of the present disclosure and do not represent all the technical spirit of the present disclosure. Accordingly, it should be appreciated that various equivalents and modified examples capable of substituting the embodiments may be made at the time of filing the present application.

In the present application, it will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance.

Unless otherwise specified, a case in which one constituent element is disposed at “a front side,” “a rear side,” “an upper side,” or “a lower side” of another constituent element includes not only a case in which one constituent element is disposed at “the front side,” “the rear side,” “the upper side,” or “the lower side” of another constituent element while directly adjoining another constituent element, but also a case in which a further constituent element is disposed between one constituent element and another constituent element. In addition, unless otherwise specified, a case in which one constituent element is “connected to” another constituent element includes not only a case in which one constituent element and another constituent element are directly connected to each other, but also a case in which one constituent element and another constituent element are indirectly connected to each other.

Hereinafter, a deposition device according to an embodiment of the present disclosure will be described with reference to the drawings.

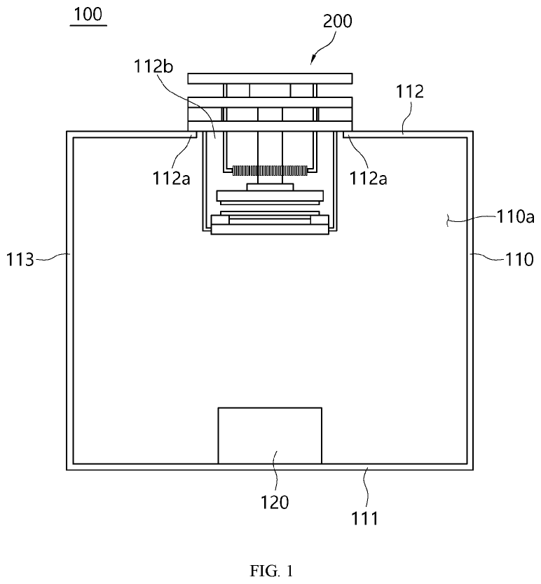

FIG. 1 is a view schematically illustrating a deposition device according to an embodiment of the present disclosure.

With reference to FIG. 1, a deposition device 100 according to an embodiment of the present disclosure includes a deposition chamber 110, a deposition source 120, and an alignment device 200.

The deposition chamber 110 provides a deposition space 110a in which deposition particles are deposited on a substrate. The deposition chamber 110 is formed in an approximately hexahedral shape. However, the deposition chamber 110 is not limited to being formed in a hexahedral shape, and the deposition chamber 110 may have various shapes that provide the deposition space 110a.

Further, the deposition chamber 110 is made of a metallic material. However, the deposition chamber 110 is not limited to being made of a metallic material, and the deposition chamber 110 may be made of various materials such as plastic with rigidity.

In addition, the deposition space 110a of the deposition chamber 110 is maintained in a vacuum ambience. Further, the deposition chamber 110 is connected to a vacuum pump (not illustrated) for maintaining the vacuum ambience. Further, the vacuum pump may be installed outside or inside the deposition chamber 110.

Further, the deposition chamber 110 includes a lower portion 111, an upper portion 112, and a plurality of lateral portions 113. The lower portion 111 has a flat plate shape. In addition, according to various embodiments of the present disclosure, the lower portion 111 may be disposed to be spaced apart from a ground surface at a predetermined interval. Further, the upper portion 112 may be disposed above the lower portion 111 and face the lower portion 111. Further, the plurality of lateral portions 113 are disposed between the lower portion 111 and the upper portion 112.

The deposition source 120 is disposed on the lower portion 111 of the deposition chamber 110. Further, the deposition source 120 accommodates deposition materials that are to be converted into deposition particles by heat. In this case, the deposition material may be an organic material or metal. Further, the deposition particles may refer to particles made when the deposition materials in a liquid or solid state are vaporized or sublimated state.

Further, the deposition source 120 has a heating part (not illustrated) configured to heat the deposition material. Further, the heating part may have a coil shape. In addition, the heating part may generate heat in a resistance method by receiving electric power or generate heat by an electromagnetic induction method.

Further, the deposition source 120 has a driving part (not illustrated) configured to move in the deposition chamber 110. The deposition source 120 moves in the deposition chamber 110 and appropriately sprays the deposition particles onto the substrate. Meanwhile, in case that the deposition source 120 moves at a lower side of the deposition chamber 110, vibration caused by the movement of the deposition source 120 may be transmitted to the deposition chamber 110.

The alignment device 200 is configured to align positions of a substrate and a mask. Further, the alignment device 200 is accommodated in the deposition space 110a of the deposition chamber 110 while being seated on the upper portion 112 of the deposition chamber 110. In this case, the upper portion 112 has catching portions 112a by which the alignment device 200 is caught. The upper portion 112 has an insertion hole 112b through which a part of the alignment device 200 is inserted into the deposition space 110a.

Therefore, the alignment device 200 may be installed to be accommodated in the deposition space 110a through the upper portion 112 of the deposition chamber 110, or the alignment device 200 is easily separated from the deposition chamber 110 through the upper portion 112 so that the alignment device 200 is maintained or repaired.

The alignment device 200 will be described below in detail with reference to the drawings.

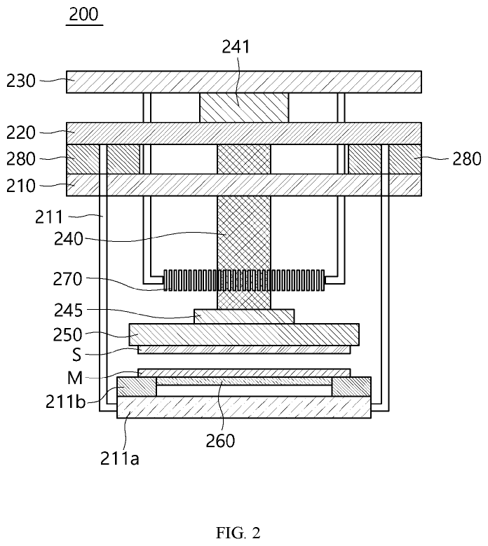

FIG. 2 is a view focusing on an interior of the deposition device according to the embodiment of the present disclosure.

With reference to FIG. 2, the alignment device 200 of the deposition device according to the embodiment of the present disclosure includes a first plate 210, a second plate 220, a third plate 230, a hexapod 240, an electrostatic chuck 250, a first support part 221, and vibration prevention parts 280.

The first plate 210 is seated on the upper portion 112 (see FIG. 1) of the deposition chamber. The first plate 210 has a flat plate shape. Further, the first plate 210 may be fixed to or separated from an upper side of the deposition chamber 110.

Therefore, when the first plate 210 is separated from the upper side of the deposition chamber 110, the interior of the deposition chamber 110 is easily maintained.

In this case, an area of the first plate 210 is larger than an area of the insertion hole 112b (see FIG. 1). The first plate 210 serves to seal the insertion hole 112b.

The second plate 220 is disposed above the first plate 210. In addition, the second plate 220 is spaced apart from the first plate 210 and disposed in parallel with the first plate 210.

The third plate 230 is disposed above the second plate 220. In addition, the third plate 230 is spaced apart from the second plate 220 and disposed in parallel with the second plate 220. In this case, the third plate 230 may be supported by the second plate 220.

The hexapod 240 includes a connection part 241 connected to the second plate 220. That is, the hexapod 240 is supported on the second plate 220 by the connection part 241.

Further, the hexapod 240 extends to the deposition space 110a while passing through the first plate 210. Further, the hexapod 240 may adjust a position of the electrostatic chuck 250. The hexapod 240 adjusts a position of a substrate S, which is fixed to the electrostatic chuck 250, by tilting the electrostatic chuck 250 and moving the electrostatic chuck 250 in an upward/downward direction by using a multi-axis structure.

Further, although not illustrated in the drawings, the hexapod 240 has a six-axis structure having six linear actuators (not illustrated). The six linear actuators operate independently.

In addition, the alignment device 200 of the deposition device according to the embodiment of the present disclosure has a position adjustment part 245 configured to adjust a planar position and gradient of the electrostatic chuck 250.

Further, after the hexapod 240 primarily adjusts the position of the electrostatic chuck 250, the position adjustment part 245 secondarily adjusts the position of the electrostatic chuck 250.

The electrostatic chuck 250 is disposed below the hexapod 240. Further, the electrostatic chuck 250 fixes the substrate S by using static electricity. In this case, the substrate S may be made of a silicon material. However, the substrate S is not limited to being made of a silicon material, and the substrate S may be made of various materials that may be fixed by the electrostatic force of the electrostatic chuck 250.

The first support part 221 extends from the second plate 220 to the deposition space 110a. Meanwhile, the first support part 221 is disposed to be spaced apart from the vibration prevention part 280 and does not interfere with the vibration prevention part 280.

Further, the first support part 221 supports a mask M that faces the substrate S. In addition, the first support part 221 has a first frame 221a disposed below the mask M. In this case, the first frame 221a has a ring shape and does not interrupt the movements of the deposition particles to the substrate S.

Further, the first support part 221 has a second frame 221b disposed above the first frame 221a. In this case, the second frame 221b supports the mask M. In addition, according to various embodiments of the present disclosure, the second frame 221b may fix the mask M by using static electricity.

Meanwhile, even though the substrate S is fixed by the electrostatic chuck 250, the substrate S is finely sagged downward by a load of the substrate S. Because of the situation in which the substrate S sags, the substrate S may have a portion formed to be finely curved. The portion formed to be curved hinders the implementation of a high-resolution display.

In order to solve this problem, the substrate S is moved downward by the hexapod 240 and pressed against the mask M. Therefore, because the substrate S is pressed against and brought into contact with the mask M, the portion of the substrate S, which is formed to be curved, is removed, and the substrate S is flattened.

The vibration prevention part 280 is disposed between the first plate 210 and the second plate 220. That is, the first plate 210 supports the vibration prevention part 280, and the vibration prevention part 280 supports the second plate 220.

Further, the vibration prevention part 280 prevents vibration of the first plate 210 from being transmitted to the second plate 220. Therefore, because the vibration of the first plate 210 is prevented from being transmitted to the hexapod 240, the position of the substrate S may be precisely adjusted by the hexapod 240.

Further, the alignment device 200 of the deposition device according to the embodiment of the present disclosure has a second support part 212 extending from any one of the second plate 220 or the third plate 230 to the deposition space 110a, and a magnetic part 270 connected to the second support part 212.

The second support part 212 is formed in parallel with the first support part 221. Further, the second support part 212 is moved in the upward/downward direction of the deposition chamber 110 by a driving part (not illustrated) provided on the third plate 230.

The magnetic part 270 is disposed above the electrostatic chuck 250. Further, in case that the second support part 212 moves downward and approaches the electrostatic chuck 250, the magnetic part 270 pulls the mask M and prevents the mask M from sagging. In this case, the mask M is made of a metallic material.

In addition, the alignment device 200 may have a mask support part 260 configured to support the mask M.

The mask support part 260 is connected to the first support part 221. Further, the mask support part 260 is made of a metallic material. Further, in case that the magnetic part 270 moves to be close to the electrostatic chuck 250, the magnetic part 270 pulls the mask support part 260.

In this case, the mask M is made of a non-magnetic material. Further, the mask M is supported by the mask support part 260, which prevents the mask M from sagging.

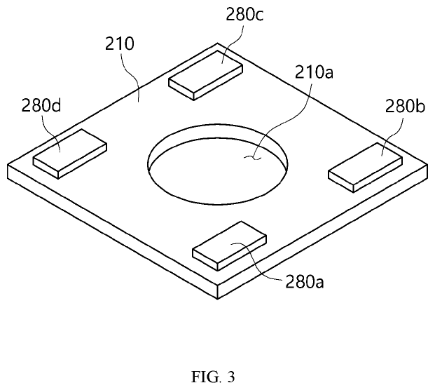

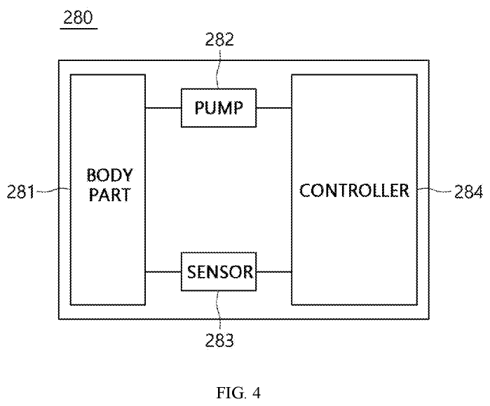

FIG. 3 is a perspective view illustrating a state in which the vibration prevention parts of the deposition device according to the embodiment of the present disclosure are disposed on the first plate, and FIG. 4 is a block diagram illustrating the vibration prevention part of the deposition device according to the embodiment of the present disclosure.

First, as illustrated in FIG. 3, the first plate 210 has a through-hole 210a penetrated by the hexapod 240 (see FIG. 2).

The vibration prevention parts 280 (see FIG. 2) are provided as a plurality of vibration prevention parts 280 including a first vibration prevention part 280a, a second vibration prevention part 280b, a third vibration prevention part 280c, and a fourth vibration prevention part 280d.

The plurality of vibration prevention parts 280 may be disposed to be spaced apart from one another at equal intervals. In addition, the plurality of vibration prevention parts 280 are disposed symmetrically with the through-hole 210a interposed therebetween. That is, the plurality of vibration prevention parts 280 are disposed symmetrically with the hexapod 240 (see FIG. 2).

Therefore, the plurality of vibration prevention parts 280 may disperse and absorb vibration of the first plate 210 (see FIG. 2).

Further, as illustrated in FIG. 4, the vibration prevention part 280 includes a body part 281, a pump 282, a sensor 283 and a controller 284.

The body part 281 may be made of a material configured to be expanded by injected air. Therefore, the body part 281 may absorb vibration of the first plate 210.

The pump 282 may be connected to the body part 281 and inject air into the body part 281

The sensor 283 may measure air pressure in the body part 281.

The controller 284 is electrically connected to the pump 282 and electrically connected to the sensor 283. Further, the controller 284 receives an electrical signal from the sensor 283, controls the pump 282, and adjusts the injection of air into the body part 281.

Therefore, the controller 284 allows the body part 281 to appropriately absorb vibration of the first plate 210 by controlling the injection of air into the body part 281.

Meanwhile, the vibration prevention part 280 is not limited to absorbing vibration in a passive manner, and the vibration prevention part 280 may absorb vibration in an active manner while using a linear motor.

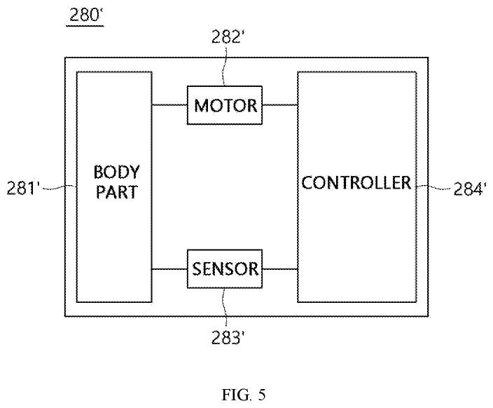

FIG. 5 is a block diagram illustrating a vibration prevention part of a deposition device according to another embodiment of the present disclosure.

With reference to FIG. 5, the vibration prevention part 280′includes a body part 281′, a vibration sensor part 283′, a vibration canceling part 282′, and a controller 284′.

The body part 281′is disposed above the first plate 210.

The vibration sensor part 283′is provided on the body part 281′and detects vibration transmitted from the first plate 210.

The vibration canceling part 282′generates an inverted sound range to cancel vibration transmitted from the first plate 210. In this case, the inverted sound range may cancel out a wavelength of the vibration transmitted from the first plate 210.

Further, the vibration canceling part 282′may include a linear motor configured to generate the inverted sound range.

The controller 284′ is electrically connected to the vibration sensor part 283′ and receives an electrical signal related to vibration from the vibration sensor part 283′.

Further, the controller 284′ controls the vibration canceling part 282′ to generate the inverted sound range in response to the electrical signal.

As described above, according to another embodiment of the present disclosure, vibration may be canceled out in an active manner by using the linear motor.

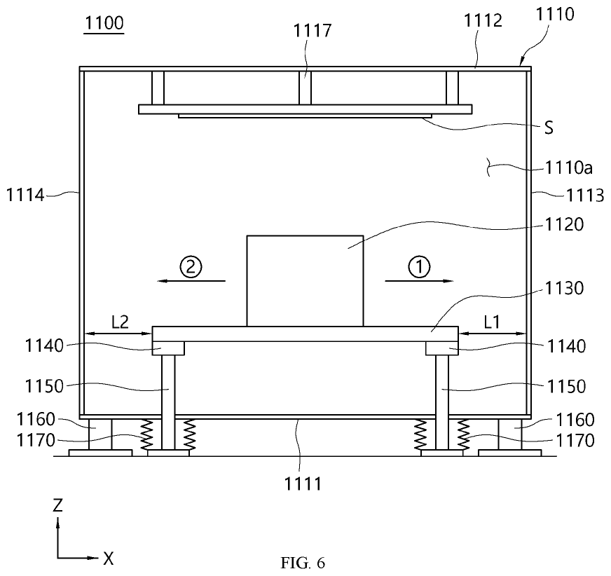

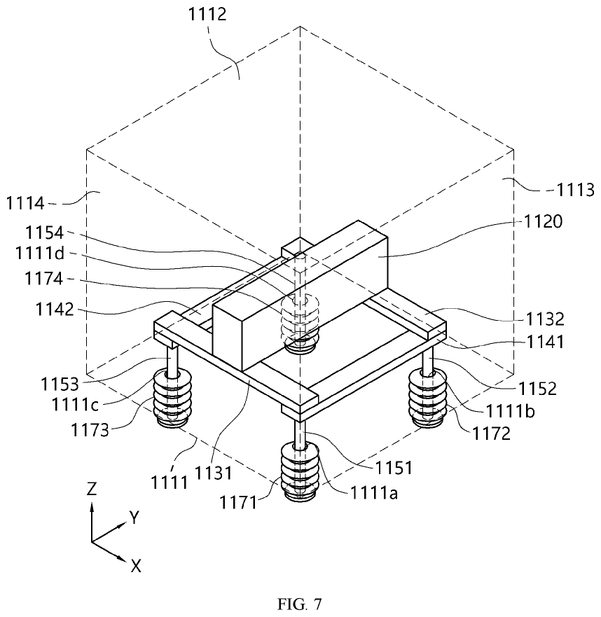

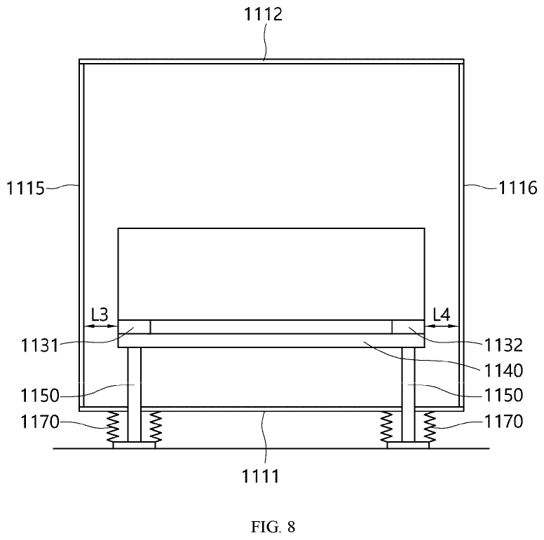

FIG. 6 is a view schematically illustrating a deposition device according to still another embodiment of the present disclosure, FIG. 7 is a perspective view schematically illustrating an interior of the deposition device according to still another embodiment of the present disclosure, and FIG. 8 is a view illustrating a state in which a guide rail is spaced apart from a deposition chamber in the deposition device according to still another embodiment of the present disclosure.

With reference to FIGS. 1 to 8, a deposition device 1100 according to still another embodiment of the present disclosure includes a deposition chamber 1110, a deposition source 1120, a guide rail 1130, a support part 1150, and an inflow prevention part 1170.

The deposition chamber 1110 accommodates the substrate S on which deposition particles are to be deposited. The deposition chamber 1110 is formed in an approximately hexahedral shape. However, the deposition chamber 1110 is not limited to being formed in a hexahedral shape, and the deposition chamber 1110 may have various shapes that accommodate the substrate S.

Further, the deposition chamber 1110 is made of a metallic material. However, the deposition chamber 1110 is not limited to being made of a metallic material, and the deposition chamber 1110 may be made of various materials such as plastic with rigidity.

In addition, an interior 1110a of the deposition chamber 1110 is maintained in a vacuum ambience. Further, the deposition chamber 1110 is connected to a vacuum pump (not illustrated) for maintaining the vacuum ambience. Further, the vacuum pump may be installed outside or inside the deposition chamber 1110.

Further, the deposition chamber 1110 includes a lower portion 1111, an upper portion 1112, and a plurality of lateral portions 1113, 1114, 1115, and 1116.

The lower portion 1111 is disposed to be spaced apart from the ground surface at a predetermined interval by spacers 1160. In this case, the spacer 1160 may be made of a metallic material having rigidity to stably support a load of the deposition chamber 1110.

In addition, according to various embodiments of the present disclosure, the spacer 1160 may include an elastic portion (not illustrated) having elasticity. Therefore, the elastic portion may prevent external vibration from being transmitted to the deposition chamber 1110 or prevent vibration, which is generated from the deposition device 1100, from being transmitted to the outside.

The upper portion 1112 is disposed above the lower portion 1111. In this case, the lower portion 1111 is disposed to face the lower portion 1111.

The plurality of lateral portions 1113, 1114, 1115, and 1116 are disposed between the lower portion 1111 and the upper portion 1112. Further, the plurality of lateral portions 1113, 1114, 1115, and 1116 include a first lateral portion 1113, a second lateral portion 1114, a third lateral portion 1115, and a fourth lateral portion 1116.

Further, the first lateral portion 1113 extends in a perpendicular direction from the lower portion 1111. Further, the second lateral portion 1114 is disposed to face the first lateral portion 1113. Further, the third lateral portion 1115 is disposed between the first lateral portion 1113 and the second lateral portion 1114. Further, the fourth lateral portion 1116 is disposed to face the third lateral portion 1115.

Further, the substrate S is disposed below the upper portion 1112 by a chuck 1117. In addition, the chuck 1117 may be an electrostatic chuck using static electricity.

In addition, at least one of the plurality of lateral portions 1113, 1114, 1115, and 1116 of the deposition chamber 1110 has a door (not illustrated) configured to open or close the interior 1110a of the deposition chamber 1110. Further, the substrate S is loaded into the deposition chamber 1110 or unloaded to the outside from the deposition chamber 1110 through the door.

The deposition source 1120 is disposed in the interior 1110a of the deposition chamber 1110. Further, the deposition source 1120 accommodates deposition materials that are to be converted into deposition particles by heat. In this case, the deposition material may be an organic material or metal. Further, the deposition particles may refer to particles made when the deposition materials in a liquid or solid state are vaporized or sublimated state.

Further, the deposition source 1120 has a heating part (not illustrated) configured to heat the deposition material. Further, the heating part may have a coil shape. In addition, the heating part may generate heat in a resistance method by receiving electric power or generate heat by an electromagnetic induction method.

Further, the deposition source 1120 has a driving part (not illustrated) configured to move in the deposition chamber 1110. The deposition source 1120 moves in the deposition chamber 1110 and appropriately sprays the deposition particles onto the substrate S.

The guide rail 1130 guides the movement of the deposition source 1120. In this case, the guide rail 1130 includes a first guide rail 1131 and a second guide rail 1132.

The first guide rail 1131 and the second guide rail 1132 are spaced apart from each other and disposed in parallel with each other. Further, the first guide rail 1131 and the second guide rail 1132 support a load of the deposition source 1120.

Therefore, the deposition source 1120 may be supported on the guide rail 1130 and move in a first direction 1 parallel to an X-axis direction or a second direction (2) that is a direction opposite to the first direction 1.

The support part 1150 is formed to penetrate the lower portion 1111 of the deposition chamber 1110. Further, the support part 1150 supports the guide rail 1130. In this case, the support part 1150 may have a rod shape. However, the support part 1150 is not limited to having a rod shape, and the support part 1150 may have various shapes that support the guide rail 1130 from the ground surface.

In addition, the support part 1150 includes a connection part 1140 configured to stably support the guide rail 1130. In this case, the connection part 1140 is disposed to intersect the guide rail 1130. For example, the connection part 1140 extends in a direction perpendicular to the guide rail 1130. Further, the connection part 1140 includes a first connection part 1141 and a second connection part 1142.

Further, the first connection part 1141 is formed in parallel with the first lateral portion 1113. The first connection part 1141 supports one side of the first guide rail 1131 and one side of the second guide rail 1132.

In this case, the first connection part 1141 is disposed to be spaced apart from the first lateral portion 1113 by a first length L1. Therefore, the first connection part 1141 prevents vibration, which is transmitted to the guide rail 1130 because of the movement of the deposition source 1120, from being transmitted to the deposition chamber 1110.

Further, the second connection part 1142 is formed in parallel with the first connection part 1141. Further, the second connection part 1142 supports the other side of the first guide rail 1131 and the other side of the second guide rail 1132. That is, the first guide rail 1131 and the second guide rail 1132 are supported by the first connection part 1141 and the second connection part 1142.

In this case, the second connection part 1142 is disposed to be spaced apart from the second lateral portion 1114 by a second length L2. Therefore, the second connection part 1142 prevents vibration, which is transmitted to the guide rail 1130 because of the movement of the deposition source 1120, from being transmitted to the deposition chamber 1110.

Meanwhile, a plurality of through-holes 1111a, 1111b, 1111c, and 1111d are formed in the lower portion 1111 and penetrated by the support part 1150. Further, the plurality of through-holes 1111a, 1111b, 1111c, and 1111d include a first through-hole 1111a, a second through-hole 1111b, a third through-hole 1111c, and a fourth through-hole 1111d.

The first through-hole 1111a is formed below one side of the first connection part 1141. Further, the second through-hole 1111b is formed below the other side of the first connection part 1141. Further, the third through-hole 1111c is formed below one side of the second connection part 1142. Further, the fourth through-hole 1111d is formed below the other side of the second connection part 1142.

In addition, the support part 1150 includes a first support part 1151, a second support part 1152, a third support part 1153, and a fourth support part 1154. The first support part 1151 passes through the first through-hole 1111a and adjoins the ground surface. Further, the first support part 1151 supports one side of the first connection part 1141. The second support part 1152 passes through the second through-hole 1111b and adjoins the ground surface. Further, the second support part 1152 supports the other side of the first connection part 1141. The third support part 1153 passes through the third through-hole 1111c and adjoins the ground surface. Further, the third support part 1153 supports one side of the second connection part 1142. The fourth support part 1154 passes through the fourth through-hole 1111d and adjoins the ground surface. Further, the fourth support part 1154 supports the other side of the second connection part 1142.

The inflow prevention part 1170 prevents air present outside the deposition chamber 1110 from being introduced through the plurality of through-holes 1111a, 1111b, 1111c, and 1111d. Further, the inflow prevention part 1170 is formed to surround a part of the support part 1150 disposed outside the vacuum chamber 1110. Therefore, even though a part of the support part 1150 is exposed to the outside of the vacuum chamber 1110 through the plurality of through-holes 1111a, 1111b, 1111c, and 1111d, the inflow prevention part 1170 seals portions between the support part 1150 and the plurality of through-holes 1111a, 1111b, 1111c, and 1111d, thereby stably maintaining a vacuum state of the interior 1110a of the deposition chamber 1110.

In this case, the inflow prevention part 1170 has a corrugated shape. For example, the inflow prevention part 1170 may have a bellows shape. Therefore, the inflow prevention part 1170 prevents sealing between the plurality of through-holes 1111a, 1111b, 1111c, and 1111d and the support part 1150 from being released by vibration transmitted through the support part 1150.

In addition, the inflow prevention part 1170 includes a first inflow prevention part 1171, a second inflow prevention part 1172, a third inflow prevention part 1173, and a fourth inflow prevention part 1174. The first inflow prevention part 1171 seals a portion between the first through-hole 1111a and the first support part 1151. The second inflow prevention part 1172 seals a portion between the second through-hole 1111b and the second support part 1152. The third inflow prevention part 1173 seals a portion between the third through-hole 1111c and the third support part 1153. The fourth inflow prevention part 1174 seals a portion between the fourth through-hole 1111d and the fourth support part 1154.

In addition, as illustrated in FIG. 8, the first guide rail 1131 is disposed in parallel with the third lateral portion 1115. In this case, the first guide rail 1131 is disposed to be spaced apart from the third lateral portion 1115 by a third length L3.

Further, the second guide rail 1132 is disposed in parallel with the fourth lateral portion 1116. In this case, the second guide rail 1132 is disposed to be spaced apart from the fourth lateral portion 1116 by a fourth length L4.

As described above, the first guide rail 1131 and the second guide rail 1132 are disposed to be spaced apart from the deposition chamber 1110, which prevents vibration, which is transmitted to the guide rail 1130 because of the movement of the deposition source 1120, from being transmitted to the deposition chamber 1110.

While the embodiments of the present disclosure have been described above, the spirit of the present disclosure is not limited to the embodiments presented in the present specification, those skilled in the art, who understand the spirit of the present disclosure, may easily propose other embodiments by adding, changing, deleting constituent elements within the same spirit and scope of the present disclosure, and it can be said that the embodiments are also within the spirit and scope of the present disclosure.

What is claimed is:

1. A deposition device, comprising:
a deposition chamber configured to provide a deposition space;
a first plate configured to be separable from an upper side of the deposition chamber;
a second plate disposed above the first plate;
a hexapod connected to the second plate and extending to the deposition space while passing through the first plate;
an electrostatic chuck disposed below the hexapod and configured to fix a substrate, wherein deposition particles are to be deposited onto the substrate;
a first support part extending from the second plate to the deposition space and configured to support a mask configured to face the substrate; and
a vibration prevention part disposed between the first plate and the second plate and configured to prevent vibration of the second plate from being transmitted to the first plate.

2. The deposition device of claim 1, wherein the vibration prevention part is provided as a plurality of vibration prevention parts, and the plurality of vibration prevention parts are disposed to be spaced apart from one another at equal intervals.

3. The deposition device of claim 1, wherein the vibration prevention part comprises:
a body part configured to be expanded by air introduced into the body part;
a pump configured to inject air into the body part; and
a controller configured to control the pump.

4. The deposition device of claim 1, wherein the vibration prevention part comprises:
a body part disposed above the first plate;
a vibration sensor part provided on the body part and configured to detect vibration;
a vibration canceling part configured to generate an inverted sound range to cancel the vibration; and
a controller configured to control the vibration canceling part in response to an electrical signal transmitted from the vibration sensor part.

5. The deposition device of claim 4, wherein the vibration canceling part comprises a linear motor configured to generate an inverted sound range.

6. The deposition device of claim 1, further comprising:
a third plate disposed above the second plate;
a second support part extending from any one of the second plate or the third plate to the deposition space and configured to move in an upward/downward direction of the deposition chamber; and
a magnetic part connected to the second support part and disposed above the electrostatic chuck.

7. The deposition device of claim 6, further comprising:
a mask support part connected to the first support part and configured to support the mask,
wherein the mask support part is made of a metallic material, and
wherein the magnetic part pulls the mask support part when the magnetic part moves to be close to the electrostatic chuck.

8. The deposition device of claim 6, wherein the mask is made of a metallic material, and
wherein the magnetic part pulls the mask when the magnetic part moves to be close to the electrostatic chuck.

9. A deposition device, comprising:
a deposition chamber configured to maintain a vacuum state and configured to accommodate a substrate, wherein deposition particles are to be deposited onto the substrate;
a deposition source accommodated in the deposition chamber and configured to spray the deposition particles;
a guide rail configured to guide a movement of the deposition source;
a support part configured to support the guide rail and penetrate a through-hole formed in a lower portion of the deposition chamber; and
an inflow prevention part configured to prevent air present outside the deposition chamber from being introduced through the through-hole.

10. The deposition device of claim 9, wherein the inflow prevention part has a corrugated shape.

11. The deposition device of claim 9, wherein the inflow prevention part is formed to surround a part of the support part disposed outside the deposition chamber.

12. The deposition device of claim 9, wherein the deposition chamber comprises:
an upper portion disposed above the lower portion, and
a plurality of lateral portions disposed between the lower portion and the upper portion,
wherein the guide rail is disposed to be spaced apart from the plurality of lateral portions at predetermined intervals.

13. The deposition device of claim 9, wherein the guide rail and the support part are not in contact with the deposition chamber.
